(19) United States
(12) Patent Application Publication
(10) Pub. No.: US 2017/0052460 A1
(43) Pub. Date: Feb. 23, 2017

(54) MASK CONTAINER AND MASK CONTAINER STORING SYSTEM

(71) Applicant: Kabushiki Kaisha Toshiba, Minato-ku (JP)

(72) Inventors: Eiji YONEDA, Miekomono (JP); Masaru Suzuki, Kuwana (JP); Hiroyuki Mizuno, Kuwana (JP); Satoshi Nagai, Yokkaichi (JP); Munetaka Machida, Kuwana (JP)

(73) Assignee: Kabushiki Kaisha Toshiba, Minato-ku (JP)

(21) Appl. No.: 14/926,380

(22) Filed: Oct. 29, 2015

Related U.S. Application Data
(60) Provisional application No. 62/207,556, filed on Aug. 20, 2015.

(51) Int. Cl. G03F 7/20

(52) U.S. Cl. CPC G03F 7/70733

(57) ABSTRACT

According to one embodiment, a mask container includes a case that houses a pattern transfer mask, and a heater. The case supports the pattern transfer mask inside the case. The heater heats the case so that the pattern transfer mask in the case has a predetermined temperature.

### CROSS-REFERENCE TO RELATED APPLICATIONS

This application is based upon and claims the benefit of priority from U.S. Provisional Application No. 62/207,556, filed on Aug. 20, 2015; the entire contents of which are incorporated herein by reference.

### FIELD

Embodiments described herein relate generally to a mask container and a mask container storing system.

### BACKGROUND

As semiconductor devices are shrunk, the wavelengths of light sources used in exposure apparatuses are becoming shorter. At present, exposure apparatuses (EUV exposure apparatuses) that use extreme ultraviolet light (hereinafter, referred to as EUV light) of a wavelength of about 100 nm or less are being applied to the manufacture of semiconductor devices. Since EUV light is attenuated in the atmosphere, exposure in a vacuum chamber is common. Therefore, EUV exposure apparatuses typically use a method of holding the back side of a mask by an electrostatic chuck when the mask is fixed to a mask stage.

A mask used in an EUV exposure apparatus is stored in a mask container. The mask container has an internal pod and an external pod. The mask is hermetically sealed and held inside the internal pod to be protected from adhesion of particles to the mask. The internal pod is hermetically sealed and held inside the external pod to be protected from adhesion of particles to the internal pod.

When the mask is transported to the EUV exposure apparatus, the mask container is set on a load port of the EUV exposure apparatus, and the internal pod is transported into a load lock chamber. At a timing when a desired reduced-pressure environment is provided in the load lock chamber, the internal pod is transported to a high-vacuum environment. The internal pod that has been transported to the high-vacuum environment is further transported to the vicinity of a mask clamp. From the internal pod that has been transported to the vicinity of the mask clamp, a top cover is removed. The internal pod with the top cover removed is disposed in proximity to the mask clamp. Then, the mask held inside the internal pod is attracted and fixed by an electrostatic force of the mask clamp.

When the mask is transported to the vicinity of the mask clamp, it is moved through the load lock chamber and the high-vacuum environment while being held in the internal pod. At this time, particles that have adhered to the surroundings of the internal pod are moved together to the vicinity of the mask clamp, being suspended around the internal pod. In this state, when the mask held inside the internal pod is attracted and fixed by the electrostatic force of the mask clamp, the particles, when harder than glass, stick in the back side of the mask, or when softer than glass, are shattered and scattered. The particles may also adhere to the front side of the mask. This results in a pattern defect.

It has been proposed to protect the front side of a reflective mask for EUV exposure apparatuses with a pellicle so that particles do not adhere to the front side. However, attenuation of EUV light in a pellicle has been great.

### BRIEF DESCRIPTION OF THE DRAWINGS

FIG. 1 is an exploded view illustrating an example of a basic configuration of a mask container according to a first embodiment;

FIGS. 2A to 2C are diagrams schematically illustrating an example of a configuration of an internal pod;

FIGS. 3A and 3B are diagrams schematically illustrating an example of a configuration of an external pod;

FIG. 4 is a diagram illustrating an example of a configuration of an EUV exposure apparatus;

FIG. 5 is a diagram schematically illustrating motion of particles when a mask case according to the first embodiment is used;

FIG. 6 is an exploded view illustrating another example of a basic configuration of a mask container according to the first embodiment;

FIG. 7 is a side view schematically illustrating an example of a configuration of an internal pod;

FIG. 8 is a cross-sectional view schematically illustrating an example of a configuration of a mask heating apparatus;

FIG. 9 is a perspective view schematically illustrating an example of a configuration of a mask stocker according to a second embodiment;

FIGS. 10A and 10B are diagrams schematically illustrating an example of a configuration of a mask case according to the second embodiment;

FIG. 11 is a perspective view schematically illustrating an example of a configuration of a mask stocker according to a third embodiment; and

FIG. 12 is a cross-sectional view schematically illustrating an example of a configuration of a mask case.

### DETAILED DESCRIPTION

According to one embodiment, a mask container includes a case that houses a pattern transfer mask, and a heater. The case supports the pattern transfer mask inside the case. The heater heats the case so that the pattern transfer mask in the case has a predetermined temperature.

Hereinafter with reference to the accompanying drawings, a mask container and a mask container storing system according to embodiments will be described in detail. These embodiments are not intended to limit the present invention.

### First Embodiment

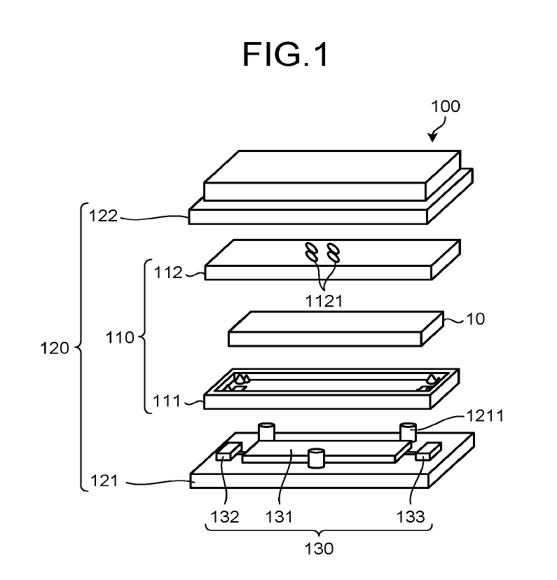

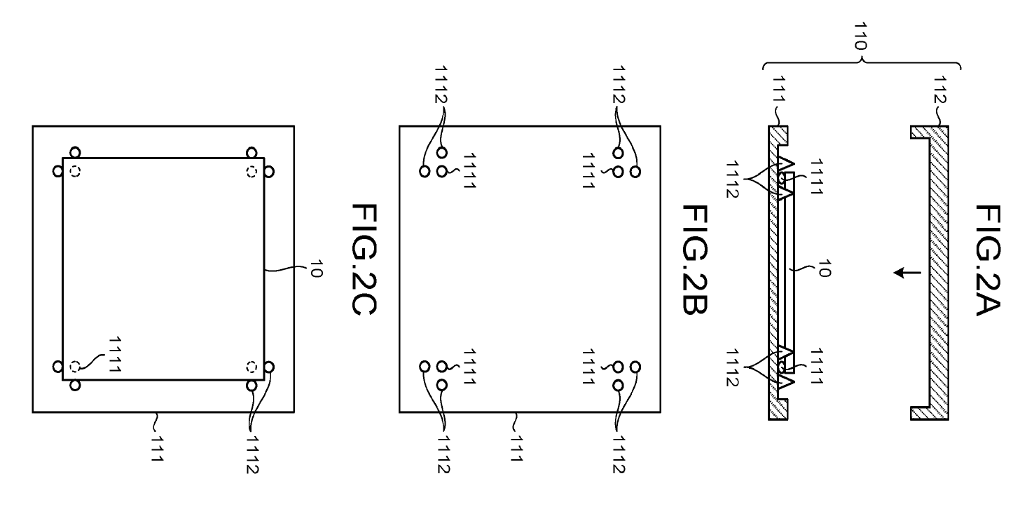

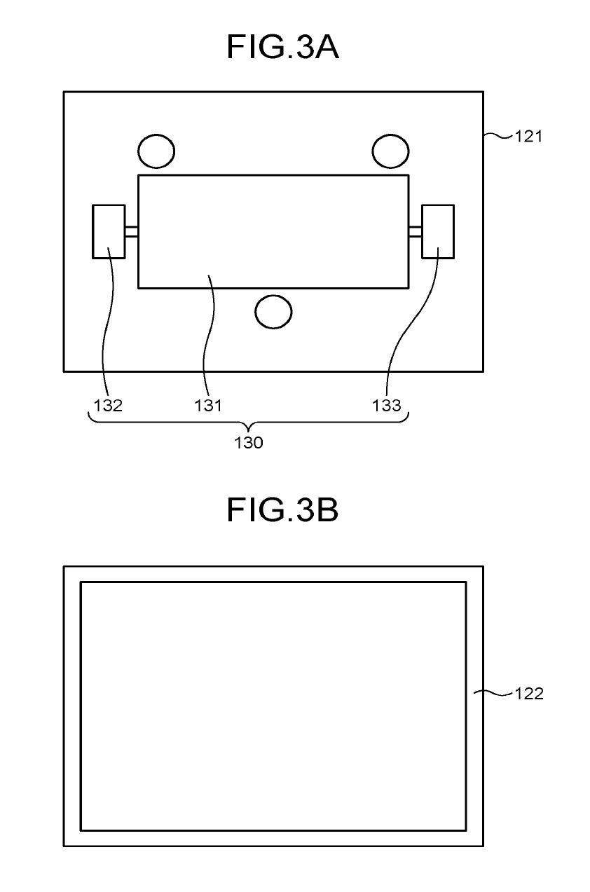

FIG. 1 is an exploded view illustrating an example of a basic configuration of a mask container according to a first embodiment. FIGS. 2A to 2C are diagrams schematically illustrating an example of a configuration of an internal pod. FIG. 2A is a side view of the internal pod. FIG. 2B is a top view of a base of the internal pod. FIG. 2C is a top view of the base of the internal pod with a mask placed thereon. FIGS. 3A and 3B are diagrams schematically illustrating an example of a configuration of an external pod. FIG. 3A is a top view of a base of the external pod. FIG. 3B is a bottom view of a cover of the external pod.

A mask case 100 has a dual pod structure including an internal pod 110 and an external pod 120. The internal pod 110 includes a base 111 and a cover 112 for housing a mask 10. The mask 10 in this description refers to a pattern transfer mask that transfers a pattern to a processed film, including a photomask, a reticle, and a template. The photomask and the reticle are the mask 10 used for performing transfer of a pattern using radiation. The template is the mask 10 with an uneven pattern formed on one principal surface of a mask substrate. The template is the mask 10 used for performing transfer of a pattern onto a processed object by hardening a resist while pressing the mask against the processed object on which the resist has been dropped. These masks 10 are sensitive, and cause a pattern defect due to adhesion of a few particles. Therefore, it is desirable to store these masks 10 under a clean atmosphere.

The base 111 is provided with a recessed portion. In the recessed portion, supporting members 1111 to support the mask 10 and guiding members 1112 to prevent a lateral shift of the mask 10 supported on the supporting members 1111 are provided. The supporting members 1111 are provided near four corners of the mask 10 of a rectangular shape, for example. The supporting members 1111 are formed by spherical members, for example, so as not to damage the mask 10.

The cover 112 is provided with filters 1121 that filter purge gas supplied from the external pod 120, and introduce it into the internal pod 110. The cover 112 is provided with a recessed portion in an area where the mask 10 is disposed, and is placed on the base 111 to block between the inside and the outside of the internal pod 110. The base 111 and the cover 112 of the internal pod 110 are made of nickel-plated aluminum, for example.

The external pod 120 includes a base 121 and a cover 122 for housing the internal pod 110. The base 121 is provided with supporting members 1211 to support the internal pod 110, and a purge gas supply opening not illustrated. The cover 122 is provided with a recessed portion in an area where the internal pod 110 is disposed, and is placed on the base 121 to block between the inside and the outside of the external pod 120. When purge gas is supplied to the external pod 120, the purge gas is discharged through a gap between the base 121 and the cover 122. The base 121 and the cover 122 of the external pod 120 are made of polyether ether ketone (PEEK) resin, for example.

In the first embodiment, a heating mechanism 130 is provided on the base 121 of the external pod 120. On a top surface of the base 121, a heat-generating member 131, a power source 132, and a control unit 133 are disposed.

The heat-generating member 131 is a member to generate heat through supply of power from the power source 132. As the heat-generating member 131, for example, a resistance wire such as a nichrome wire, a Peltier element, or the like can be used. As illustrated in FIGS. 3A and 3B, the heat-generating member 131 is disposed in a position corresponding to the position of a principal surface of the internal pod 110.

The power source 132 supplies power to the heat-generating member 131. The power source 132 supplies power so that the heat-generating member 131 has a temperature higher than or equal to 40° C. and lower than a temperature at which the mask 10 stored in the mask case 100 is thermally deformed.

The control unit 133 switches on and off heat generation by the heat-generating member 131. Switching on and off of the supply of power to the heat-generating member 131 by the control unit 133 may be performed at a predetermined timing, or may be performed according to an external signal.

A temperature measurement unit not illustrated to measure a temperature at a predetermined positon in the mask case 100 may be provided for the control unit 133 to perform feedback control on power supplied to the heat-generating member 131 so that a temperature measured by the temperature measurement unit becomes a target value.

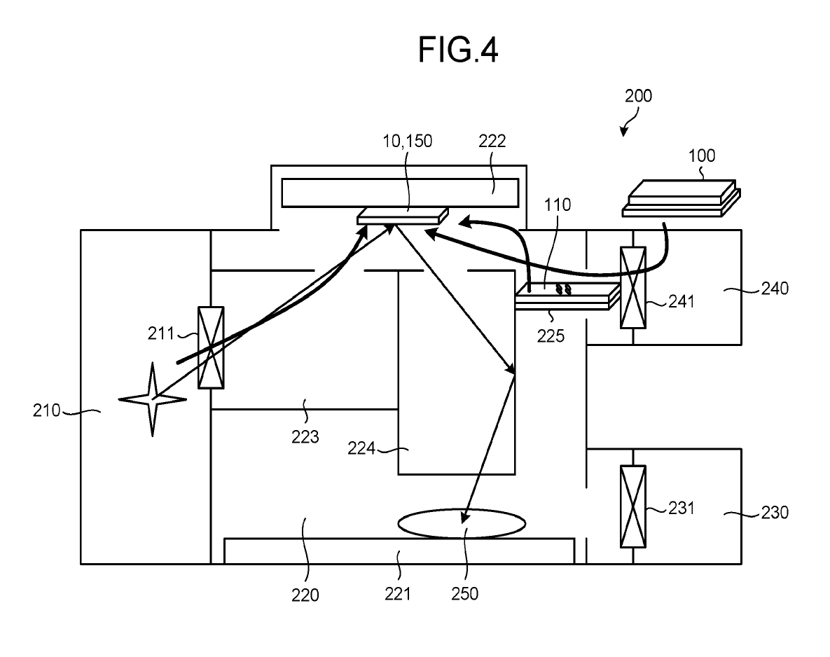

Next, a method for using the mask case 100 with this configuration will be described. Hereinafter, an example of mounting the mask 10 to a mask stage of an EUV exposure apparatus will be provided. FIG. 4 is a diagram illustrating an example of a configuration of an EUV exposure apparatus. An EUV exposure apparatus 200 includes a light source 210, a processing chamber 220, a wafer load lock chamber 230, and a mask load lock chamber 240. The light source 210, the processing chamber 220, the wafer load lock chamber 230, and the mask load lock chamber 240 are evacuated by a vacuum pump to respective predetermined degrees of vacuum inside.

The light source 210 generates EUV light to be used for exposure processing, and emits the EUV light to the processing chamber 220. A gate valve 211, for example, is provided between the light source 210 and the processing chamber 220. When the exposure processing is performed, the gate valve 211 is opened to guide the EUV light into the processing chamber 220.

The processing chamber 220 is a space where the exposure processing is performed. In the processing chamber 220, a wafer stage 221 to hold a wafer 250 to be processed, a mask stage 222 to hold the mask 10, an illumination optical system 223 to guide the EUV light from the light source 210 to the mask 10, a projection optical system 224 to guide the EUV light reflected from the mask 10 onto the wafer 250, and a buffer 225 to hold the internal pod 110 carried in from the mask load lock chamber 240 are provided.

The wafer load lock chamber 230 is a relay chamber for transport of the wafer 250 between the outside of the EUV exposure apparatus 200 and the processing chamber 220. A gate valve 231 is provided between the wafer load lock chamber 230 and the processing chamber 220.

The mask load lock chamber 240 is a relay chamber for transport of the mask 10 between the outside of the EUV exposure apparatus 200 and the processing chamber 220. A gate valve 241 is provided between the mask load lock chamber 240 and the processing chamber 220.

The mask 10 is stored in the mask case 100 illustrated in FIGS. 1 to 3B outside the EUV exposure apparatus 200. Specifically, the mask 10 is held inside the internal pod 110 and hermetically sealed to be isolated from an external environment. This protects the mask 10 from adhesion of particles. The internal pod 110 is held inside the external pod 120 and hermetically sealed to be isolated from an external environment. This protects the internal pod 110 from adhesion of particles.

In a normally stored state of the mask 10, the control unit 133 controls so that energy is supplied from the power source 132 to the heat-generating member 131. This causes the heat-generating member 131 to generate heat, heating the internal pod 110 and the inside mask 10 to a predetermined temperature. When a temperature measurement unit to measure the temperature of the internal pod 110 or the mask 10 is provided, feedback control is performed so that a temperature measured by the temperature measurement unit becomes a predetermined temperature. Thus, the mask 10 is stored in a heated state.

Next, processing of mounting the mask 10 heated in the mask case 100 to the mask stage 222 in the EUV exposure apparatus 200 will be described. First, the internal pod 110 is taken out from the external pod 120 of the mask case 100, and the internal pod 110 is moved to a load port. The mask load lock chamber 240 in the EUV exposure apparatus 200 is set to atmospheric pressure. Then, the internal pod 110 is transported into the mask load lock chamber 240. At this time, the control unit 133 of the mask case 100 switches off power supply from the power source 132 to the heat-generating member 131. It may switch off power supply from the power source 132 to the heat-generating member 131 at a predetermined timing before movement to the load port so that the temperature of the mask 10 when mounted to the mask stage 222 becomes less than a predetermined temperature. In this case, the time until the mask 10 decreases from a heated temperature to a predetermined temperature, that is, the timing to switch off power supply can be estimated, using heat dissipation characteristics of the mask 10 under atmospheric pressure and under vacuum.

Subsequently, the mask load lock chamber 240 is evacuated by a vacuum pump not illustrated to provide a predetermined reduced-pressure environment inside. The gate valve 241 is opened at a timing when the predetermined reduced-pressure environment has been provided, to transport the internal pod 110 of the mask case 100 to the buffer 225 in the processing chamber 220. Then, the gate valve 241 is closed to provide a predetermined degree of vacuum in the processing chamber 220.

Subsequently, the internal pod 110 is transported by a transfer arm not illustrated from the buffer 225 to the vicinity of the mask stage 222. Then, the cover 112 of the internal pod 110 is removed, and the base 111 of the internal pod 110 is disposed in proximity to the mask stage 222 by the transfer arm not illustrated. Specifically, the base 111 is disposed so that the mask 10 on the base 111 faces the mask stage 222 with a predetermined distance between them. Then, the mask 10 is attracted and fixed to the mask stage 222 by an electrostatic force of the mask stage 222.

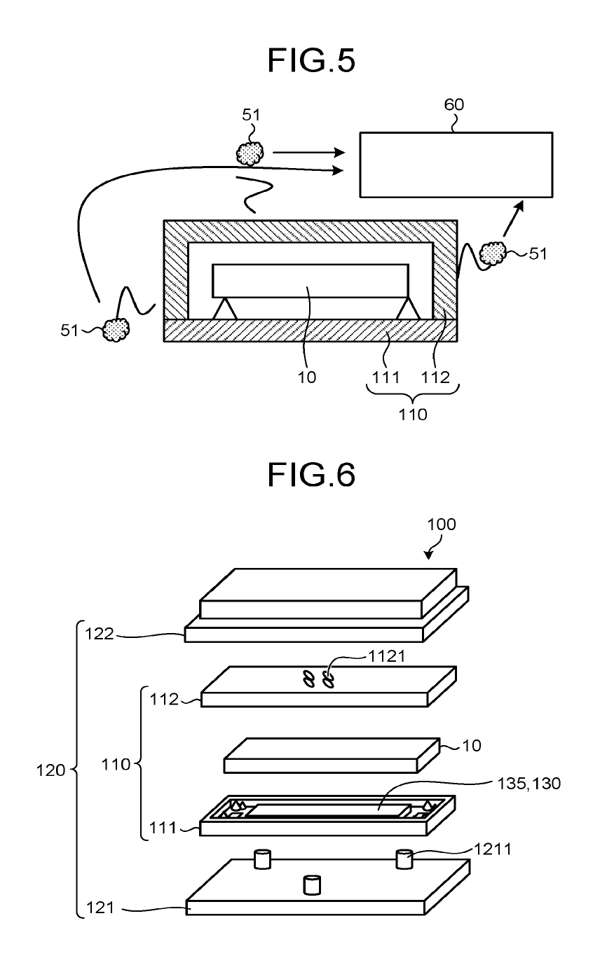

In the above-described process, the state of particles when the internal pod 110 is transported into the mask load lock chamber 240 and into the processing chamber 220, and immediately before the mask 10 is mounted to the mask stage 222 will be described. FIG. 5 is a diagram schematically illustrating motion of parties when the mask case according to the first embodiment is used. In FIG. 5, an example when the internal pod 110 is transported into the EUV exposure apparatus 200 is provided.

The internal pod 110 placed in the EUV exposure apparatus 200 has thermal energy due to heating by the heating mechanism 130 of the external pod 120. Therefore, the internal pod 110 generates a thermophoretic force against particles 51 present in the vicinity. The thermophoretic force is a force to move particles toward a low-temperature region 60 from the internal pod 110 and the mask 10 having a temperature higher than a temperature in the EUV exposure apparatus 200. The low-temperature region 60 is members constituting the EUV exposure apparatus 200, for example. This thermophoretic force keeps the particles 51 away from the internal pod 110.

Likewise, when the mask 10 is mounted from the internal pod 110 to the mask stage 222, the mask 10 generates, by thermal energy, a thermophoretic force against particles 51 present in the vicinity of the mask 10. This keeps the particles 51 away from the mask 10. As a result, when the mask 10 is mounted, particles 51 caught between the mask 10 and the mask stage 222, and particles 51 adhering to the front side of the mask 10 can be reduced.

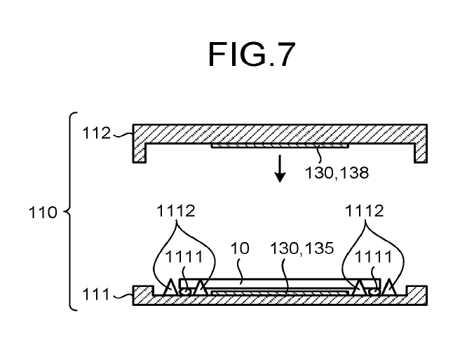

In the above description, a case where the heating mechanism 130 is provided to the external pod 120 has been described. Alternatively, the heating mechanism 130 may be provided to the internal pod 110. FIG. 6 is an exploded view illustrating another example of a basic configuration of a mask container according to the first embodiment. FIG. 7 is a side view schematically illustrating an example of a configuration of an internal pod.

Unlike in FIGS. 1 to 3B, the external pod 120 is provided with the power source 132 and the control unit 133 but is not provided with the heat-generating member 131. Alternatively, the internal pod 110 is provided with heat-generating members 135 and 138. The heat-generating members 135 and 138 are provided on inside surfaces of the internal pod 110. Specifically, on the base 111, the heat-generating member 135 is disposed in a recessed portion in which the mask 10 is supported. The heat-generating member 138 is disposed in a recessed portion of the cover 112. As illustrated in FIG. 7, the heat-generating members 135 and 138 are disposed in positions corresponding to the position of a principal surface of the mask 10.

The power source 132 of the external pod 120 performs power supply by a magnetic-field resonance method, for example, to the heat-generating members 135 and 138 of the internal pod 110. The power source 132 supplies power so that the heat-generating member 135 has a temperature higher than or equal to 40° C. and lower than a temperature at which the mask 10 is thermally deformed.

The control unit 133 switches on and off heat generation by the heat-generating members 135 and 138 at a predetermined timing. Switching on and off of the supply of power to the heat-generating members 135 and 138 by the control unit 137 may be performed according to an external signal. Also in this case, a temperature measurement unit to measure a temperature at a predetermined positon in the internal pod 110 may be provided for the control unit 137 to perform feedback control on power supplied to the heat-generating members 135 and 138 so that a temperature measured by the temperature measurement unit becomes a target value.

When the heat-generating members 135 and 138 are provided to the internal pod 110 like this, the internal pod 110 is transported to the vicinity of the mask stage 222 in the processing chamber 220 of the EUV exposure apparatus 200. That is, the mask 10 is transported while being stored in a heated state.

The above description has illustrated a case where the mask 10 is housed in the mask case 100, and then heating of the mask 10 is started by the heating mechanism 130 of the mask case 100. However, before the mask 10 is housed in the mask case 100, it may be heated in advance by a mask heating apparatus or the like.

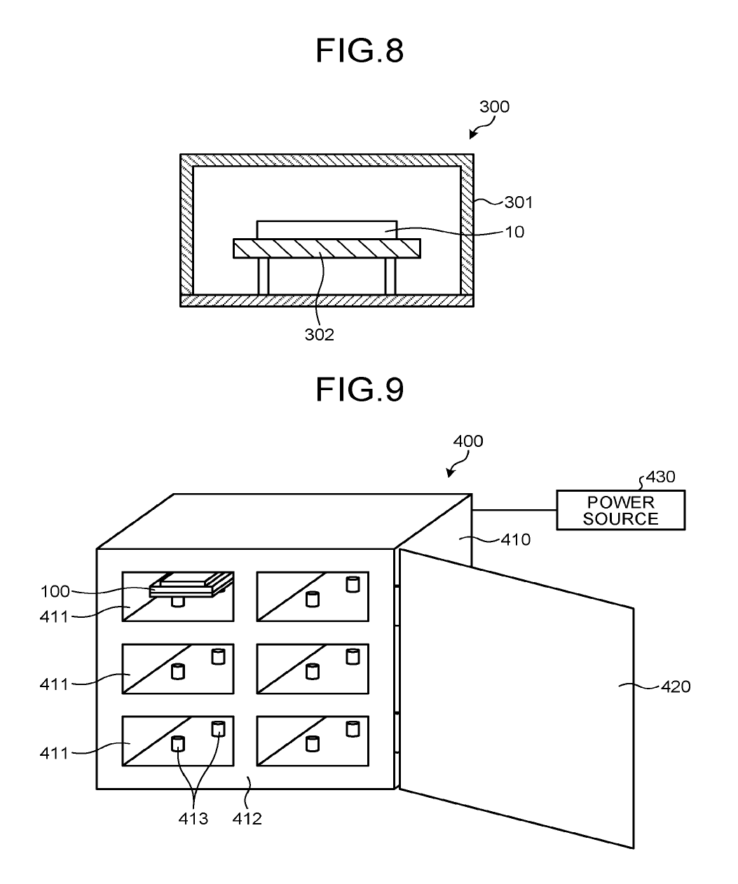

FIG. 8 is a cross-sectional view schematically illustrating an example of a configuration of a mask heating apparatus. A mask heating apparatus 300 has a structure in which a baking plate 302 is disposed in a processing chamber 301. The baking plate 302, on which the mask 10 is placed, has a function of heating the mask 10. The baking plate 302 is heated by power supplied from a power source not illustrated. The mask 10 is heated to a temperature higher than or equal to 40° C. at which the mask 10 is not thermally deformed. Then, the heated mask 10 is housed in the above-described mask case 100. By heating the mask 10 before housing the mask 10 in the mask case 100 like this, a heat gradient is produced between the mask 10 and a surrounding area when the mask 10 is put into the mask case 100. This makes it difficult for suspended particles to come close to the mask 10, allowing a reduction in the number of particles entering the internal pod 110.

The mask heating apparatus 300 in FIG. 8 heats the mask 10 using the baking plate 302. Alternatively, it may heat the mask 10 using a flash lamp.

In the first embodiment, the heating mechanism 130 to heat the mask 10 is provided to the mask case 100, and the mask 10 is stored and transported while the mask 10 is heated to a temperature at which the mask 10 is not thermally deformed. Therefore, a thermophoretic force of the heated mask 10 can prevent suspended particles from coming close to the mask 10 when the mask 10 is mounted to a mask stage in a vacuum apparatus. As a result, it is possible to reduce the number of particles caught between the mask stage and the mask 10, and reduce the number of particles adhering to the front side of the mask 10.

The mask 10 is put into the mask case 100 after the mask 10 is heated. Therefore, a heat gradient caused by the mask 10 having been heated can prevent suspended particles from coming close to the mask 10 also when the mask 10 is put into the mask case 100. As a result, it is possible to prevent adhesion of particles to the mask 10 when the mask 10 is housed in the mask case 100.

### Second Embodiment

In the first embodiment, a case where a heating mechanism is provided to a mask case has been described. In a second embodiment, a case where a mask stocker to store a mask case and the mask case are combined to heat a mask in the mask case will be described.

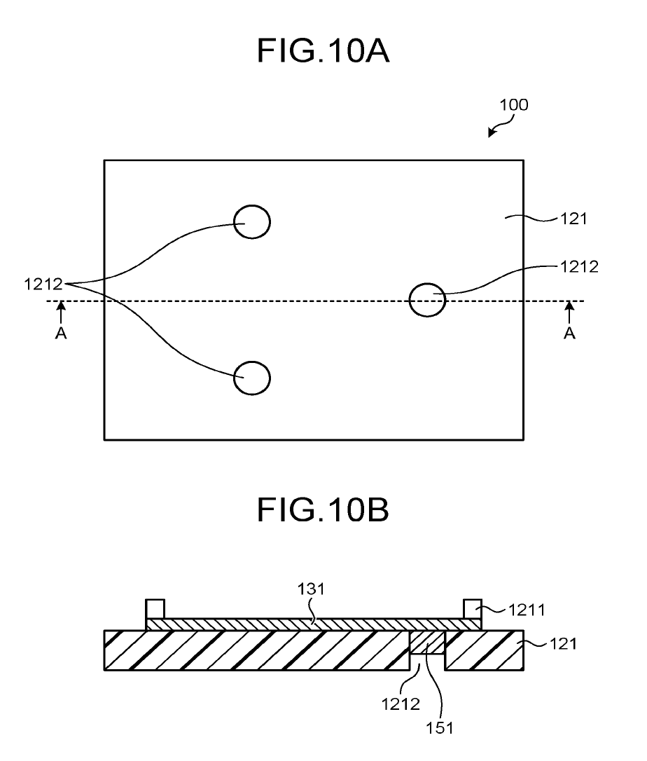

FIG. 9 is a perspective view schematically illustrating an example of a configuration of a mask stocker according to the second embodiment. FIGS. 10A and 10B are diagrams schematically illustrating an example of a configuration of a mask case according to the second embodiment. FIG. 10A is a bottom view of an external pod of the mask case. FIG. 10B is a cross-sectional view along A-A in FIG. 10A.

A mask stocker 400 is a container to store a plurality of mask cases 100. As illustrated in FIG. 9, the mask stocker 400 has a container body 410, a lid 420, and a power source 430. The container body 410 is cuboid in outside shape and hollow, and has a shape with one surface of the cuboid outside shape opened. The interior of the container body 410 is partitioned by a partitioning member 412. Spaces partitioned by the partitioning member 412 constitute storage rooms 411 in which the mask cases 100 are stored.

Supporting members 413 to support the bottom of the mask case 100 and supply power to the mask case 100 are provided on the bottom of each storage room 411. The supporting members 413 are made of a conductive material, and electrically connected to the power source 430. For example, the supporting members 413 are provided in an arrangement of a triangular shape on the bottom of the storage room 411. The number of the supporting members 413 provided to the storage room 411 can be determined optionally.

The lid 420 is openably and closably provided to the opened surface of the container body 410. By closing the lid 420, the inside of the storage rooms 411 is isolated from the outside. The power source 430 supplies power to each supporting member 413 in the container body 410.

The structure of the mask case 100 stored in the mask stocker 400 like this is different from that of the mask case 100 in the first embodiment. Specifically, it is a structure in which, on the top surface of the base 121 of the external pod 120 of the mask case 100 in FIGS. 1 to 3B, only the heat-generating member 131 is provided, and the power source 132 and the control unit 133 are removed. Further, in the undersurface of the base 121, through holes 1212 penetrating therethrough in a thickness direction are provided. The through holes 1212 are provided in positions corresponding to the placement positions of the supporting members 413 in the mask stocker 400. In each through hole 1212, a contact 151 made of a conductive material is embedded. An upper end of the contact 151 is connected to the heat-generating member 131. A lower end of the contact 151 is located inside the undersurface of the base 121, forming a recessed portion. The diameter of the through holes 1212 is a dimension that allows insertion of the supporting members 413. The other components of the mask case 100 are identical to those illustrated in FIGS. 1 to 2C and FIG. 3B, and will not be described.

When the mask case 100 is placed on the supporting members 413 in the storage room 411 of the mask stocker 400, the supporting members 413 and the contacts 151 are electrically connected. As a result, power is supplied to the heat-generating member 131, heating the interior of the mask case 100. The supporting members 413 are fitted into the recessed portions (through holes 1212) of the base 121, and thus the mask case 100 is in a state of being fixed lightly by the supporting members 413. With this, although the mask case 100 may be slightly moved in an in-plane direction in the storage room 411, the mask case 100 can be prevented from being moved in the storage room 411.

In the second embodiment, the supporting members 413 to support the mask case 100 and perform supply of power to the mask case 100 are provided in each storage room 411 of the mask stocker 400. In the mask case 100, the through holes 1212 corresponding in position to the supporting members 413 are provided in the base 121 of the external pod 120, and the contacts 151 connected to the heat-generating member 131 that is disposed on the top surface of the base 121 are embedded in the through holes 1212. With this, when the mask case 100 is supported on the supporting members 413 in the storage room 411 of the mask stocker 400, current flows from the supporting members 413 through the contacts 151 to the heat-generating member 131, starting heating of the interior of the mask case 100 by the heat-generating member 131. As a result, it is possible to prevent particles suspended inside the mask case 100 from adhering to the internal pod 110 and the mask 10 also during storage in the mask stocker 400.

By disposing the supporting members 413 in a triangular shape, the disposition orientation of the mask case 100 in the storage room 411 is defined. Thus, it is possible to facilitate realizing the propriety of an insertion direction of the mask case 100 when the mask case 100 is stored in the storage room 411.

### Third Embodiment

In the second embodiment, a case where supporting members to hold a mask case and supply power are provided in each storage room of a mask stocker, and the mask stocker itself does not heat mask cases has been described. In a third embodiment, a case where a mask stocker itself heats mask cases will be described.

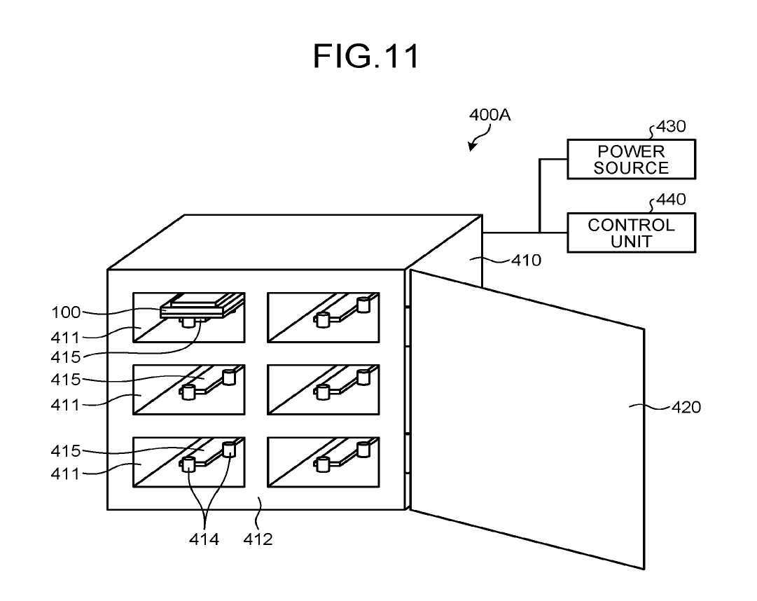

FIG. 11 is a perspective view schematically illustrating an example of a configuration of a mask stoker according to the third embodiment. A mask stocker 400A includes a container body 410, a lid 420, a power source 430, and a control unit 440. The container body 410 is cuboid in outside shape and hollow, and has a shape with one surface of the cuboid outside shape opened. The interior of the container body 410 is partitioned by a partitioning member 412. Spaces partitioned by the partitioning member 412 constitute storage rooms 411 in which mask cases 100 are stored.

Supporting members 414 to support the bottom of the mask case 100, and a heat-generating member 415 provided in a position corresponding to the placement position of the mask case 100 are provided on the bottom of each storage room 411. The supporting members 414 are provided in an arrangement of a triangular shape on the bottom of the storage room 411, for example. The number of the supporting members 414 provided to each storage room 411 can be determined optionally. The heat-generating member 415 is connected to the power source 430 through wiring not illustrated. The heat-generating member 415 may be provided on a top surface or a side surface of the storage room 411.

The lid 420 is openably and closably provided to a surface of the container body 410 on the side where the storage rooms 411 are provided. By closing the lid 420, the storage rooms 411 can be brought into a state of being isolated from the outside. The power source 430 supplies power to the heat-generating member 415 provided in each storage room 411.

The control unit 440 switches on and off the supply of power to the heat-generating members 415 in the storage rooms 411. The control unit 440 may uniformly control switching of the supply of power on all the storage rooms 411, or may perform switching of the supply of power for each storage room 411. A temperature measurement unit to measure a temperature in the storage rooms 411 may be provided for the control unit 440 to perform feedback control on power supplied to the heat-generating members 415 so that a temperature measured by the temperature measurement unit becomes a target value.

As the mask case 100 stored in the mask stocker 400A like this, the mask case 100 described in the first embodiment can be used.

The third embodiment can also provide an effect similar to that of the second embodiment.

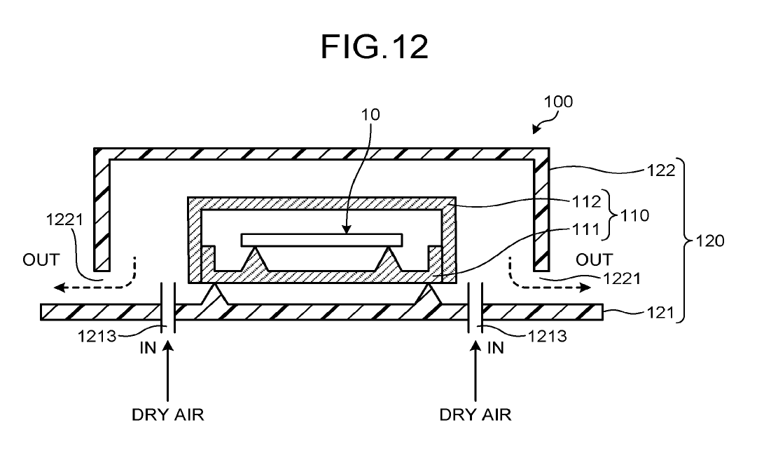

The second and third embodiments have illustrated a case where the mask case 100 is stored in the masks stocker 400 or 400A. When the mask case 100 is put in the masks stocker 400 or 400A, dry air is passed into the mask case 100 to prevent adhesion of dust or the like. FIG. 12 is a cross-sectional view schematically illustrating an example of a configuration of a mask case. As described above, in the mask case 100, the internal pod 110 houses the mask 10, and the external pod 120 houses the internal pod 110. Gas supply openings 1213 through which dry air is supplied to a space inside the external pod 120 are provided in the base 121 of the external pod 120. Gas discharge openings 1221 through which dry air is discharged are provided in the cover 122 of the external pod 120.

In the masks stocker 400 or 400A, dry air is supplied. The dry air is supplied through the gas supply openings 1213 of the external pod 120 into the mask case 100, and discharged through the gas discharge openings 1221, thereby to prevent adhesion of dust or the like to the internal pod 110. Inside the external pod 120, the dry air is supplied through a purge gas supply opening not illustrated into the internal pod 110, and discharged through the filters 1121, thereby to prevent adhesion of dust or the like to the mask 10.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A mask container comprising:
a case that houses a pattern transfer mask, the case supporting the pattern transfer mask inside the case; and
a heater that heats the case so that the pattern transfer mask in the case has a predetermined temperature.

2. The mask container according to claim 1, wherein
the heater includes
a heat-generating member provided to the case, and
a power source that supplies power to the heat-generating member.

3. The mask container according to claim 2, wherein
the case includes
a first pod that houses the pattern transfer mask, the first pod supporting the pattern transfer mask inside the first pod, and
a second pod that houses the first pod, the second pod supporting the first pod inside the second pod.

4. The mask container according to claim 3, wherein the heater is provided to the second pod.

5. The mask container according to claim 4, wherein the heater is provided inside the second pod.

6. The mask container according to claim 3, wherein the heater is provided to the first pod.

7. The mask container according to claim 6, wherein the heater is provided outside the first pod.

8. The mask container according to claim 2, wherein the power source supplies power to the heat-generating member so that the temperature of the pattern transfer mask is in a temperature range higher than or equal to 40° C. and lower than a temperature at which a material of which the pattern transfer mask is made is thermally deformed.

9. The mask container according to claim 2, wherein the heater further includes a control unit that controls the supply of power from the power source to the heat-generating member.

10. The mask container according to claim 9, wherein
the heater further includes a temperature measurement unit that measures a temperature in the case, and
the control unit controls the supply of power from the power source to the heat-generating member so that a temperature obtained by the temperature measurement unit becomes a target value.

11. The mask container according to claim 2, wherein the heat-generating member is disposed in a position corresponding to the position of a principal surface of the pattern transfer mask in the case.

12. A mask container storing system comprising:
a mask container that houses a pattern transfer mask; and
a mask stocker that stores the mask container, wherein
the mask stocker includes
a hollow container body with one surface opened,
a lid provided openably and closably to the opened surface of the container body,
a partitioning member that partitions the interior of the container body into a plurality of storage rooms, the storage rooms being capable of storing the mask container,
a supporting member provided on a bottom surface of the storage rooms to support the mask container, the supporting member being made of a conductive material, and
a power source that supplies power to the supporting member, and
the mask container includes
a case that houses the pattern transfer mask, the case supporting the pattern transfer mask inside the case,
a heat-generating member that heats the case so that the pattern transfer mask in the case has a predetermined temperature, the heat-generating member being disposed in an area including a bottom surface of the case, and
a contact provided in the bottom surface of the case, the contact being a conductive material embedded in a through hole provided in a position corresponding to a disposed position of the supporting member in the bottom surface of the case, one end of the contact being connected to the heat-generating member, the other end of the contact being located in the through hole.

13. The mask container storing system according to claim 12, wherein the power source supplies power to the heat-generating member so that the temperature of the pattern transfer mask is in a temperature range higher than or equal to 40° C. and lower than a temperature at which a material of which the pattern transfer mask is made is thermally deformed.

14. A mask container storing system comprising:
a mask container that houses a pattern transfer mask; and
a mask stocker that stores the mask container, wherein
the mask stocker includes
a hollow container body with one surface opened,
a lid provided openably and closably to the opened surface of the container body,
a partitioning member that partitions the interior of the container body into a plurality of storage rooms, the storage rooms being capable of storing the mask container,
a supporting member provided on a bottom surface of the storage rooms to support the mask container,
a first heat-generating member provided in the storage rooms, and
a first power source that supplies power to the first heat-generating member, and
the mask container includes
a case that houses the pattern transfer mask, the case supporting the pattern transfer mask inside the case, and
a heater that heats the case so that the pattern transfer mask in the case has a predetermined temperature.

15. The mask container storing system according to claim 14, wherein the first power source supplies power to the first heat-generating member so that the temperature of the pattern transfer mask is in a temperature range higher than or equal to 40° C. and lower than a temperature at which a material of which the pattern transfer mask is made is thermally deformed.

16. The mask container storing system according to claim 14, wherein the mask stocker further includes a first control unit that controls the supply of power from the first power source to the first heat-generating member.

17. The mask container storing system according to claim 16, wherein
the mask stocker further includes a temperature measurement unit that measures a temperature in the storage rooms, and
the first control unit controls the supply of power from the first power source to the first heat-generating member so that a temperature obtained by the temperature measurement unit becomes a target value.

18. The mask container storing system according to claim 14, wherein
the heater includes
a second heat-generating member provided to the case, and
a second power source that supplies power to the second heat-generating member.

19. The mask container storing system according to claim 18, wherein
the case includes
a first pod that houses the pattern transfer mask, the first pod supporting the pattern transfer mask inside the first pod, and
a second pod that houses the first pod, the second pod supporting the first pod inside the second pod.

20. The mask container storing system according to claim 18, wherein the heater further includes a second control unit that controls the supply of power from the second power source to the second heat-generating member.
